(19) United States
(12) Patent Application Publication
(10) Pub. No.: US 2024/0345492 A1
(43) Pub. Date: Oct. 17, 2024

(54) SENSOR SYSTEM

(71) Applicant: ASML NETHERLANDS B.V., Veldhoven (NL)

(72) Inventor: Gijs KRAMER, Nijmegen (NL)

(73) Assignee: ASML NETHERLANDS B.V., Veldhoven (NL)

(21) Appl. No.: 18/683,389

(22) PCT Filed: Aug. 8, 2022
(86) PCT No.: PCT/EP2022/072234

§ 371 Date: Feb. 13, 2024

(30) Foreign Application Priority Data
Sep. 13, 2021 (EP) 21196357.4
Nov. 29, 2021 (EP) 21211143.9

(51) Int. Cl. G03F 7/00; G01B 11/06; G01B 11/245; G03F 9/00

(52) U.S. Cl. CPC G03F 7/7085; G01B 11/0608; G01B 11/245; G03F 7/70783; G03F 9/7034; G01B 2210/50

(57) ABSTRACT

A sensor system for measuring a shape of a substrate, the sensor system include: a substrate support to support a surface of the substrate; at least one sensor device, each sensor device including an optical emitter to emit radiation onto the surface of the substrate, and an optical receiver to receive the radiation reflected from the surface; and a controller. The controller is configured to: determine at least one measurement height of the surface of the substrate above each of the at least one sensor device, based on the received radiation; compensate for gravitational sag of the substrate relative to a calibration height; and determine the shape of the substrate based on a comparison of the calibration height and the at least one measurement height.

### CROSS-REFERENCE TO RELATED APPLICATIONS

This application claims priority of EP application 21196357.4 which was filed on 13 Sep. 2021, and EP application 21211143.9 which was filed on 29 Nov. 2021, and which are incorporated herein in their entirety by reference.

### FIELD

The present invention relates to a sensor system for measuring a shape of a substrate, for example for measuring a shape of a wafer.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) at a patterning device (e.g., a mask) onto a layer of radiation-sensitive material (resist) provided on a substrate (e.g., a wafer).

To project a pattern on a substrate a lithographic apparatus may use electromagnetic radiation. The wavelength of this radiation determines the minimum size of features which can be formed on the substrate. Typical wavelengths currently in use are 365 nm (i-line), 248 nm, 193 nm and 13.5 nm. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Low-k₁ lithography may be used to process features with dimensions smaller than the classical resolution limit of a lithographic apparatus. In such process, the resolution formula may be expressed as CD=k₁×λ/NA, where λ is the wavelength of radiation employed, NA is the numerical aperture of the projection optics in the lithographic apparatus, CD is the “critical dimension” (generally the smallest feature size printed, but in this case half-pitch) and k₁ is an empirical resolution factor. In general, the smaller k₁ the more difficult it becomes to reproduce the pattern on the substrate that resembles the shape and dimensions planned by a circuit designer in order to achieve particular electrical functionality and performance. To overcome these difficulties, sophisticated fine-tuning steps may be applied to the lithographic projection apparatus and/or design layout. These include, for example, but not limited to, optimization of NA, customized illumination schemes, use of phase shifting patterning devices, various optimization of the design layout such as optical proximity correction (OPC, sometimes also referred to as “optical and process correction”) in the design layout, or other methods generally defined as “resolution enhancement techniques” (RET). Alternatively, tight control loops for controlling a stability of the lithographic apparatus may be used to improve reproduction of the pattern at low k1.

During the lithographic process, in which patterned layers are arranged on top each other, a substrate may, for example due to the internal stresses in or between the layers, become warped. These warped substrates have still to be properly handled by the devices used in the lithographic process. With increasing demands on the internal structure within the layers and the quantity of layers, e.g. about 200 layers, positioned on top of each other, the proper handling of warped substrates is becoming increasingly important.

### SUMMARY

The inventor has identified that in known systems, wafer warpage information is currently entered into an exposure recipe (i.e. settings defining how components of the lithographic apparatus handle substrates and/or settings defining how components of the lithographic apparatus are controlled to expose the substrates to radiation and/or settings defining how substrates are measured by the lithographic apparatus) that is used for a batch of multiple wafers. This is necessary to prevent damage (to both the lithographic apparatus and to the substrates themselves), prevent time (throughput) loss, and enable successful clamping and takeovers. Using the wafer warpage information is also needed to optimize exposure accuracy (overlay), which is currently attempted with known systems with limited success by varying a wafer clamp flow rate setting.

However, actual warpage information is not currently used in known systems and instead, a maximum/estimated value of possible warpage is entered into an exposure recipe. If the real warpage is higher than the estimated value, which is in turn higher than the maximum warpage capacity of the substrate handling devices of the lithographic apparatus, damage to wafer and components of the lithographic apparatus can ensue.

Furthermore wafer-to-wafer variations are not taken into account and thus the option to optimize performance per wafer is not possible.

Gravitational sag may occur at locations on a wafer where there is no active support, for example, when a wafer is supported at its center the edges around its circumference will be subject to gravitational sag. Such sag can account for warpage values on the order of 0.1 mm and should be accounted for in warpage. A known sensor determines the warpage of a wafer by supporting it vertically relative to its planar surface, such that gravitational sag is minimized. However, measurement of the warpage outside of a lithographic apparatus is time consuming, labour intensive, expensive and, when gravitational sag is not taken into account, also suffers from poor accuracy.

According to one aspect of the present disclosure there is provided a sensor system for measuring a shape of a substrate (e.g. a wafer), comprising: a substrate support to support a surface of the substrate, at least one sensor device, each sensor device comprising an optical emitter to emit radiation beams onto the surface of the substrate, and an optical receiver to receive the radiation beams reflected from the surface; and a controller configured to: determine at least one measurement height of the surface of the substrate above each of the at least one sensor device, based on the received radiation beams; compensate for gravitational sag of the substrate relative to a calibration height; and determine the shape of the substrate based on a comparison of the calibration height and the at least one measurement height.

The calibration height may be predetermined and is obtained by retrieving the calibration height from a memory coupled to the controller.

The controller may be configured to obtain the calibration height based on received radiation beams reflected from a surface of a test substrate supported by the substrate support.

The controller may be configured to determine the at least one measurement height of the surface of the substrate above each of the at least one sensor device while the substrate and the at least one sensor device are rotated relative to each other.

The substrate support may be configured to rotate relative to the at least one sensor device. The at least one sensor device may be configured to rotate relative to the substrate support.

The controller may be configured to determine the at least one measurement height of the surface of the substrate above each of the at least one sensor device while the substrate and the at least one sensor device are moved linearly relative to each other.

The substrate support may be configured to move linearly relative to the at least one sensor device. The at least one sensor device may be configured to move linearly relative to the substrate support.

The controller may be configured to determine the at least one measurement height of the surface of the substrate above each of the at least one sensor device while the substrate and the at least one sensor device are rotated relative to each other by an angle of less than 270 degrees, preferably less than 225 degrees, and more preferably less than 180 degrees.

The controller may be configured to determine the at least one measurement height of the surface of the substrate above each of the at least one sensor device while the substrate and the at least one sensor device are rotated relative to each other by an angle of less than 135 degrees, preferably less than 90 degrees, and more preferably less than 45 degrees.

The controller may be configured to determine the at least one measurement height of the surface of the substrate above each of the at least one sensor device while the substrate and the at least one sensor device are rotationally stationary.

The substrate support may be configured to vacuum clamp the substrate to the substrate support.

The at least one sensor device may comprise: a first sensor device positioned along a first radius of the substrate; and a second sensor device position along a second radius of the substrate, the first radius different to the second radius.

The first sensor device may be the only sensor device of the at least one sensor device that is positioned along the first radius.

The second sensor device may be the only sensor device of the at least one sensor device that is positioned along the second radius.

The first radius and the second radius are separated by an angle between 45 and 270 degrees, preferably between 90 and 225 degrees, more preferably between 135 and 180 degrees.

The at least one sensor device may comprise: a third sensor device positioned along a third radius of the substrate, the third radius different to the first radius and the second radius.

The third sensor device may be the only sensor device of the at least one sensor device that is positioned along the third radius.

The at least one sensor device may comprise only a single sensor device.

One or more of the at least one sensor device may be a confocal chromatic sensor device.

According to one aspect of the present disclosure there is provided a lithographic apparatus comprising the sensor system described herein.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic overview of a lithographic cell;

FIG. 3 depicts a pre-aligner and substrate handler;

FIG. 4 depicts the pre-aligner and substrate handler with a wafer placed on the pre-aligner;

FIG. 5 depicts the pre-aligner and substrate handler with a wafer on the substrate handler, which is extended;

FIG. 6 depicts a schematic block diagram of components of a lithographic apparatus;

FIG. 7 depicts a top view of a substrate support arranged to support a surface of a substrate;

FIG. 8 depicts a side view of the substrate support supporting a surface of a substrate; and

FIG. 9 depicts a top view of sensor devices arranged relative to a substrate support.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a in target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

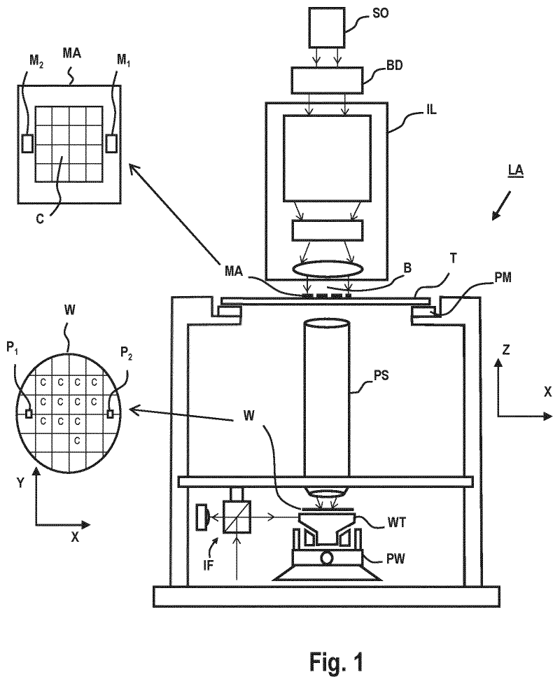

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axes, i.e., an x-axis, a y-axis and a z-axis. Each of the three axes is orthogonal to the other two axes. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

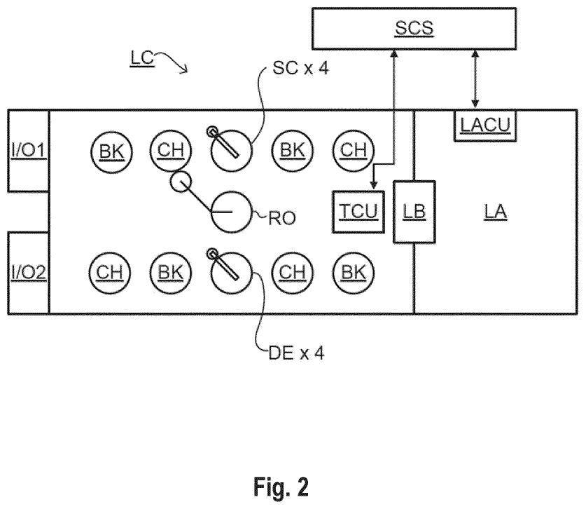

As shown in FIG. 2 the lithographic apparatus LA may form part of a lithographic cell LC, also sometimes referred to as a lithocell or (litho) cluster, which often also includes apparatus to perform pre- and post-exposure processes on a substrate W. Conventionally these include spin coaters SC to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

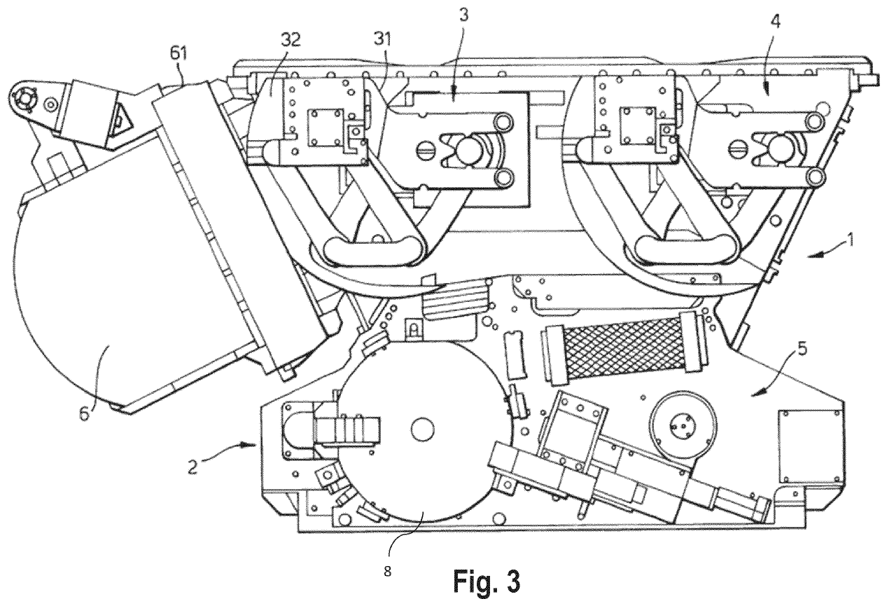

FIG. 3 shows a pre-align unit 1 comprising a pre-aligner 2 and wafer handling components. After a wafer has been transferred from a wafer carrier or process track to the pre-aligner 2, the pre-alignment process is started. Pre-alignment may include wafer edge detection, e.g. using an optical sensor, wafer centering and temperature conditioning.

Once pre-alignment is complete, the wafer is transferred to a wafer table WT by a load robot 3 (the “substrate handler”). The load robot 3 is equipped with an independent and separate trajectory safeguard system in order to prevent wafer breakage. During operation of the load robot 3, measured absolute position and derived velocity of the load robot 3 are compared with permitted position and velocity. Remedial action can be taken in the event of divergence.

The position of the wafer on the pre-aligner 2 is known with high accuracy and it must be placed on the wafer table WT with the required accuracy, i.e. within the capture range of the alignment system employed at the wafer table WT. To this end, the load robot 3 is provided with a docking unit (the “coupling means”) 31 which couples to the pre-aligner 2 when taking up the wafer W and to the wafer table WT when putting it down. The docking unit 31 may be of the ball/groove kinematic coupling type with the ball provided on the docking unit 31 and grooves on the pre-aligner 2 and wafer table WT. Preferably, the docking unit 31 couples to the pre-aligner 2 and wafer table WT at two spaced apart positions. For safety reasons the rotating part of the load robot 3 is provided with a light shield 32 to prevent any stray light from the exposure position escaping to the pre-align unit 1 or process track.

After full exposure, an unload robot 4 transfers the wafer W from the wafer table WT to a discharge station 5. The unload robot 4 may be constructed similarly to the load robot 3, but does not have such high accuracy requirements. The wafer W is taken from the discharge station 5, also referred to as the pedestal, to the wafer carrier 6 or process track. The unload robot 4 can also be used to load wafers from the pre-aligner 2 to the wafer table WT. Conversely, the load robot 3 can also be used to transfer wafers from the wafer table WT to the discharge station 5 or the wafer carrier 6.

The pre-align unit 1 may further be provided with a carrier handler 61 which enables the use of different types of wafer carriers, such as 200 mm and 300 mm cassette carriers. The carrier handler 61 can be configured on either the left or right side of the lithographic projection apparatus and arranges for accepting and (if applicable) locking the wafer carrier 6, inspecting and indexing the wafer carrier 6 and (if applicable) opening the carrier 6 and removing wafers. The carrier handler 61 can be used to store rejected wafers or wafers that need further processing, in the wafer carrier 6. The pre-aligner 2 comprises a temperature stabilizing unit (TSU) 8, which brings a wafer to a predetermined temperature.

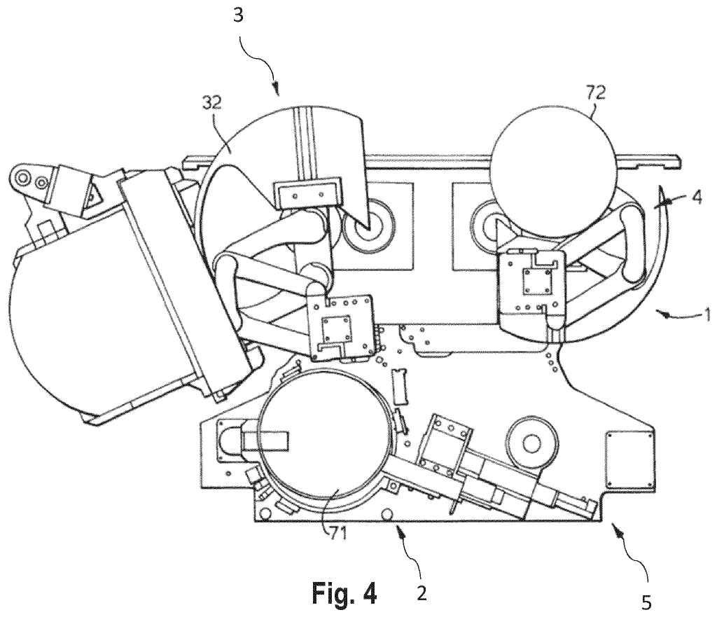

In FIG. 4, the pre-align unit 1 is shown in a first loaded position. In this position, the pre-aligner 2 contains a wafer 71, which has been pre-aligned and conditioned, while the load robot 3 is positioned to transfer the wafer 71, after half rotation of the load robot 3, to the wafer table WT. The unload robot 4 carries a wafer 72, which has been removed from the wafer table WT after exposure, and which, after half rotation of the unload robot 4, will be transferred to the discharge station 5.

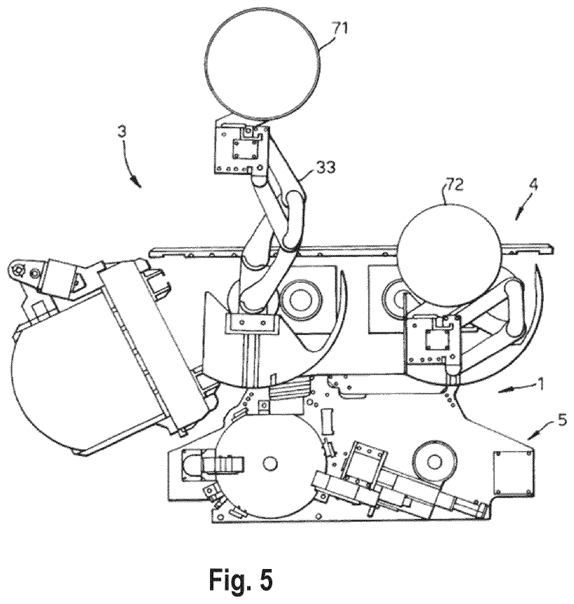

In FIG. 5, the same pre-align unit 1 is shown but with arm 33 of the load robot 3 extended for transfer of wafer 71 to the wafer table WT. The exposed wafer 72 is still on the unload robot 4.

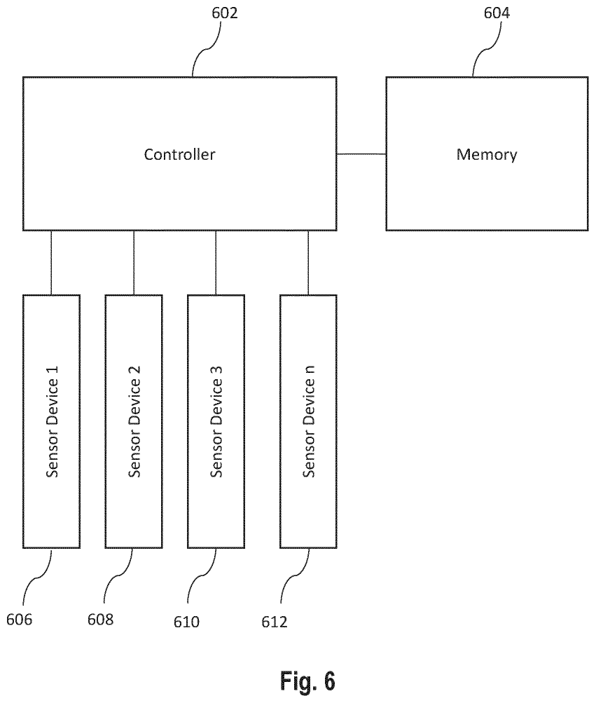

FIG. 6 depicts a schematic block diagram of components of the lithographic apparatus LA. In particular, FIG. 6 illustrates a controller 602 coupled to a memory 604 and one or more sensor devices 606-612.

The functionality of the controller 602 described herein may be implemented in code (software) stored on a memory (e.g. memory 604) comprising one or more storage media, and arranged for execution on a processor comprising one or more processing units. The storage media may be integrated into and/or separate from the controller 602. The code is configured so as when fetched from the memory and executed on the processor to perform operations in line with embodiments discussed herein. Alternatively, it is not excluded that some or all of the functionality of the controller is implemented in dedicated hardware circuitry (e.g. ASIC(s), simple circuits, gates, logic, and/or configurable hardware circuitry like an FPGA).

Each of the one or more sensor devices 606-612 are arranged to emit light towards a surface of a wafer and detect light reflected from that surface of the wafer in order to determine the distance between the sensor device and the surface of the wafer.

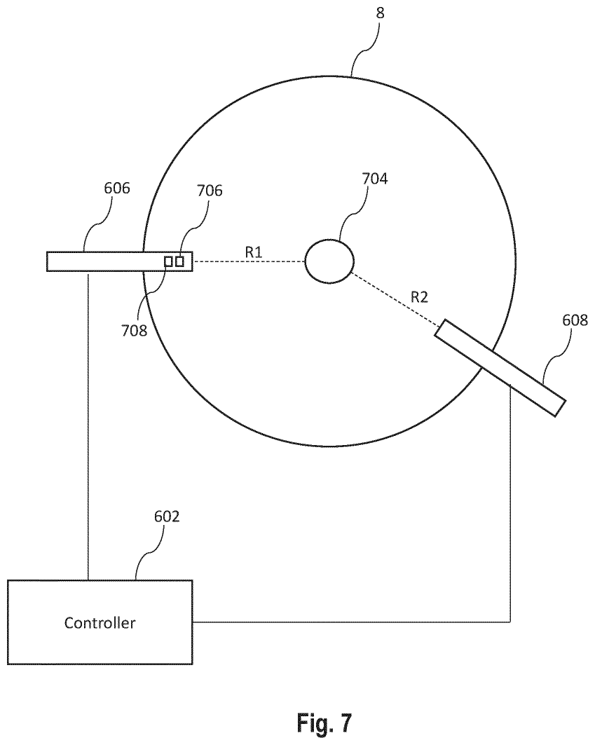

FIG. 7 illustrates a top view of two sensor devices (a first sensor device 606 and a second sensor device 608) that are integrated into the TSU 8, thus the sensor system is in-line in a pre-align unit of e.g., a lithographic apparatus. It will be appreciated that the number of sensor devices may vary to that shown in FIG. 7. FIG. 7 illustrates a substrate support 704 that is arranged to support a surface of a wafer. In the example of FIG. 7 the substrate support 704 supports the wafer at the center of the wafer. In this example the substrate support 704 may be a circular wafer chuck that clamps the wafer in a defined, warpage representative state, using vacuum clamping, and the upper surface of the substrate support 704 supports the wafer. When the wafer is supported at its center at a known calibration height above the one or more sensor devices 606-612, the one or more sensor devices 606-612 are used to measure the height of the surface of the wafer at the outer region (near the edge) of the wafer in order to determine the shape of the wafer. A benefit of using a known calibration height is that possible deformations due to additional wafer clamps can be accounted for.

The calibration height may be determined by a number of means, including but not limited to those disclosed herein. For example, a perfectly flat and stiff workpiece or tool having a known warpage and thickness may be used, positioned above the sensor devices 606, 608. The local heights are then measured with reference to the flat and level surface of the workpiece. Gravitational sag may then be compensated based on a lookup table or formula corresponding to the actual warpage. Alternatively, a reference wafer may be used in the same way as a dedicated workpiece, wherein the reference wafer is positioned above the sensor devices 606, 608. The local heights are then measured with reference to a flat wafer subject to gravitational sag. Such a reference wafer may be an arbitrary flat wafer, or a known tool wafer. Gravitational sag may then be compensated based on a lookup table or formula corresponding to the actual warpage. Interpolation of the gravitational sag may also be possible. In a further alternative, a calibration height may be determined by measuring a tool or flat wafer at different radii. The local heights are then measured at different radii, which together may comprise measurement points over a line segment, with reference to a flat wafer subject to gravitational sag. Gravitational sag may then be compensated based on a lookup table or formula corresponding to the actual warpage. Interpolation of the gravitational sag may also be possible. Furthermore, due to the different height impact over the radius, gravitational sag may be distinguished from warpage. Another means of compensation of gravitational sag may be achieved via reference to the sensor device location, wherein sensor devices are positioned on tolerances and the surface through the zero-positions of the sensor devices are used as a measurement reference. The local heights are then measured with reference to the tolerance-based sensor devices, and uncorrected warpage can be determined. Gravitational sag may then be compensated based on a lookup table or formula corresponding to the actual warpage.

In alternative embodiments, the substrate support 704 may comprise two or more edge supports that are arranged to support the wafer at its edges at a known calibration height above the one or more sensor devices 606-612. In these alternative embodiments, the one or more sensor devices 606-612 are used to measure the height of the surface of the wafer near the center of the wafer in order to determine the shape of the wafer.

As shown in FIG. 7, each sensor device comprises an optical emitter 706 to emit radiation beams onto a lower surface of the wafer, and an optical receiver 708 to receive the radiation beams reflected from the lower surface. The radiation beams may be emitted onto the lower surface of the wafer from a direction that is perpendicular to a flat horizontal plane of the wafer. The one or more sensor devices 606-612 may be confocal chromatic sensors. This is advantageous because confocal chromatic measurement principle has a good balance of range (several mm), accuracy (sub-μm) and robustness for various wafer backsides (shiny, Si, SiO, SiN, polySi, SiON) even at slight local wafer angles (due to warpage shape for instance). Furthermore, by using the confocal chromatic measurement principle, phase transitions can be measured also on transparent substrates of sufficient thickness, and therefore sensors of this type may be used to detect backside water droplets. It should be noted that the radiation beams do not have to be confocal and chromatic, e.g. white light interferometry may be used.

The one or more sensor devices 606-612 do not perform a full-surface shape measurement (although more than the edge vs center is possible). That is, in embodiments of the present invention a full map of the surface of the wafer is not required from the sensor measurements to derive the shape of the wafer.

In operation, the controller 602 is configured to: (i) determine at least one measurement height of the surface of the wafer above each of the one or more sensor devices 606-612, based on the reflected radiation beams received by the optical receiver(s) 708; (ii) compensate for gravitational sag of the wafer relative to a calibration height; and (iii) determine the shape of the wafer based on a comparison of the calibration height and the height measurements. The controller 602 may determine the measurement height of the surface of the wafer above each of the one or more sensor devices 606-612 before the wafer is clamped and pre-aligned on the TSU 8.

In embodiments where the height of the substrate support 704 above the TSU 8 is kept the same for all measurements (e.g. by mechanical means that fix the height of the sensor devices relative to the height of the substrate support 704), the controller 602 may retrieve the calibration height from the memory 604 coupled to the controller 602. In embodiments, where the height of the substrate support 704 above the TSU 8 is not kept the same for all measurements (e.g. if the height of the substrate support 704 cannot be reliably positioned at a fixed height above the TSU 8), the controller 602 may be configured to obtain the calibration height based on received radiation beams reflected from a surface of a test wafer with known warpage (preferably flat) that is supported by the substrate support 704 during a calibration process.

By comparison of the calibration height and the measured height of the surface of the wafer above the sensor(s) warpage can be detected when the height of the surface of the wafer above the sensor(s) is greater than or less than the calibration height. The controller 602 may fit a shape model to the height measurements to determine the shape of the wafer. The shape model may describe a saddle, bowl, umbrella or half pipe shape of the wafer, corresponding to the shape of the typical warpage of the respective wafer that will occur during the lithographic process in which multiple layers are added on the wafer. A fit of the theoretical edge height profile (double sine, due to Stoney's equation) yields the peak+valley and thus the warpage X/Y numbers, and also a measure for the goodness-of-fit (how well the measured height data conforms to the theoretically expected shape defined by the shape model). For example, two sensor devices positioned at 180 degrees apart should sense the same measurement heights of the wafer, if they do not, this is indicative of an imperfection in the wafer and will be reflected in the measure for the goodness-of-fit.

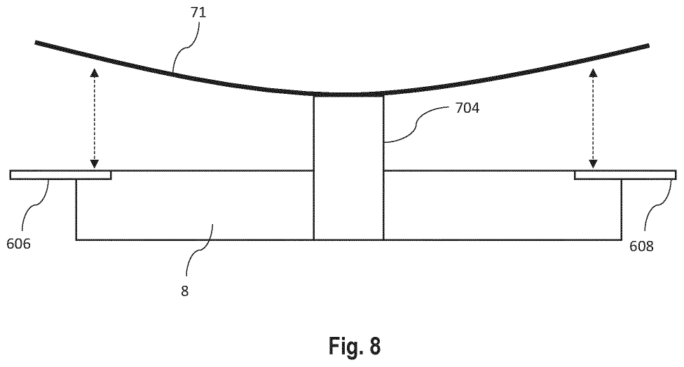

FIG. 8 shows a side view of the arrangement shown in FIG. 7 with the substrate support 704 supporting a lower surface of a wafer 71. The wafer 71 shown in FIG. 8 has a relatively extreme warpage. In practice, the warpage of the wafer 71 will normally be substantially smaller with respect to the diameter of the wafer 71.

In some embodiments, during measurement of the shape of the wafer 71 the wafer 71 and the one or more sensor devices 606-612 are rotated relative to each other. This may be achieved by rotation of the substrate support 704 or the TSU 8 (in which the one or more sensor devices 606-612 are integrated).

When rotating a full circumference, the most data is gathered (and even the individual sensor heads can be compared versus each other for better accuracy) however this comes at the cost of the time taken to perform the measurements.

Thus, the controller 602 may be configured to determine the height of the lower surface of the wafer 71 above each of the one or more sensor devices 606-612 while the wafer and the at least one sensor device are rotated relative to each other by an angle of less than 270 degrees, preferably less than 225 degrees, and more preferably less than 180 degrees.

To reduce the time taken to perform the measurements further, the controller may be configured to determine the height of the lower surface of the wafer above each of the at least one sensor device while the wafer and the at least one sensor device are rotated relative to each other by an angle of less than 135 degrees, preferably less than 90 degrees, and more preferably less than 45 degrees.

When only a single sensor device is used i.e. the first sensor device 606, the wafer 71 and the first sensor device 606 may be rotated relative to each other for the full circumference of the wafer (i.e. by an angle 360 degrees). However this is not essential and the wafer and the at least one sensor device may be rotated relative to each other by an angle of less than 360 degrees.

Additionally, or alternatively, during measurement of the shape of the wafer 71 the wafer 71 and the one or more sensor devices 606-612 may be moved linearly relative to each other. This may be achieved by linear actuation of the substrate support 704 and/or the TSU 8 (in which the one or more sensor devices 606-612 are integrated). The linear movement of the sensor devices relative to the wafer may be combined with a relative rotation of the sensor devices and the wafer. The combination of linear and rotational movement of the sensor devices relative to the wafer can advantageously result in measurement of a larger area in a shorter period of time.

It will be appreciated that increasing the number of sensor devices and positioning the multiple sensor devices at appropriate places in the TSU 8, reduces the amount of rotation and/or linear movement and therefore time required to perform the measurements.

FIGS. 7 and 8 illustrate an example whereby two sensor devices (a first sensor device 606 and a second sensor device 608) are integrated into the TSU 8. When the wafer is supported by the substrate support 704, the first sensor device 606 is positioned along a first radius R1 such that the optical emitter 706 and the optical receiver 708 of the first sensor device 606 are underneath the wafer. The first sensor device 606 may be the only sensor device that is positioned along the first radius R1. That is, in some embodiments there is not a “string” of sensor devices positioned along the first radius R1 given that a full map of the wafer is not required to derive the shape of the wafer. When the wafer is supported by the substrate support 704, the second sensor device 608 is positioned along a second radius R2 such that the optical emitter 706 and the optical receiver 708 of the second sensor device 608 are underneath the wafer. The second sensor device 608 may be the only sensor device that is positioned along the second radius R2. That is, in some embodiments there is not a “string” of sensor devices positioned along the second radius R2 given that a full map of the wafer is not required to derive the shape of the wafer.

The first sensor device 606 may be separated from the second sensor device 608 by an angular spacing of between 45 and 270 degrees, preferably between 90 and 225 degrees, more preferably between 135 and 180 degrees.

When only two sensor devices are used, the wafer 71 and the two sensor devices may be rotated relative to each other for the full circumference of the wafer. However this is not essential and the wafer and the two sensor devices may be rotated relative to each other by an angle of less than 360 degrees. For example, the wafer and the two sensor devices may be rotated relative to each other by an angle of between 30 and 180 degrees, more preferably by an angle of between 45 and 90 degrees. During rotation of the wafer 71 relative to the two sensor devices, each of the two sensor devices gathers multiple distance measurements of the height of the wafer above the respective sensor device. As a mere example, each of the two sensor devices may gather 10 measurements during a 45 degree rotation of the wafer 71 relative to the two sensor devices, where each measurement is taken from a different portion of the wafer.

The optical emitter 706 and the optical receiver 708 of the first sensor device 606 is positioned a first distance away from the central substrate support 704 along the first radius R1. The optical emitter 706 and the optical receiver 708 of the second sensor device 608 is positioned a second distance away from the central substrate support 704 along the first radius R2, whereby the first and second distances may be the same or different.

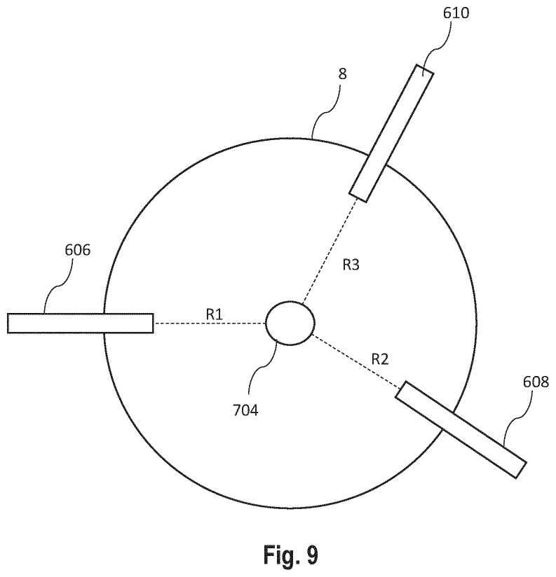

Three or more sensor devices may be integrated into the TSU 8. FIG. 9 illustrates an example whereby three sensor devices (a first sensor device 606, a second sensor device 608, and a third sensor device 610) are integrated into the TSU 8.

When the wafer is supported by the substrate support 704, the third sensor device 610 is positioned along a third radius R3 of the wafer. The third sensor device 610 may be the only sensor device that is positioned along the third radius R3. That is, in some embodiments there is not a “string” of sensor devices positioned along the third radius R3 given that a full map of the wafer is not required to derive the shape of the wafer.

The optical emitter 706 and the optical receiver 708 of the third sensor device 606 is positioned a third distance away from the central substrate support 704 along the third radius R3. The third distance may be the same or different to the first and second distances.

The three sensor devices may be separated from each other by an angular spacing of 120 degrees, or approximately 120 degrees (e.g. two of the three sensor devices may be separated from each other by an angular spacing of between 110 and 130 degrees).

When three sensor devices are used, the wafer 71 and the three sensor devices may be rotated relative to each other for the full circumference of the wafer. However this is not essential and the wafer and the three sensor devices may be rotated relative to each other by an angle of less than 360 degrees. For example, the wafer and the two sensor devices may be rotated relative to each other by an angle of between 45 and 180 degrees, preferably by an angle of between 90 and 135 degrees, and more preferably by an angle of 120 degrees. It will be appreciated that with more sensor devices the full circumference of the wafer can be scanned with less rotation span.

Whilst FIG. 9 shows three sensor devices, as noted above three or more sensor devices may be integrated into the TSU 8 and used in accordance with embodiments of the present disclosure to measure the shape of the wafer.

In some embodiments, the measurement of the shape of the wafer 71 is performed during a centering phase during which the wafer 71 and the one or more sensor devices 606-612 are rotated relative to each other. The centering phase is required for putting the wafer on the wafer table WT with sufficient X/Y/Rz accuracy. The centering phase consists of a radial displacement when the wafer is rotated to a specific angular (Rz) orientation on the central substrate support 704 to correct for two degrees of freedom 2DOF. Before the correction, the eccentricity is determined by rotating the wafer on the substrate support 704 and measuring the wafer edge position and the angular orientation of a notch on the wafer. After centering, this measurement is repeated as a check. Therefore this rotation movement could also be used for a simultaneous height measurement in accordance with embodiments of the present disclosure.

We have described above how during measurement of the shape of the wafer 71, the wafer 71 and the one or more sensor devices 606-612 may be moved linearly or rotated relative to each other. In other embodiments in which multiple sensor devices are used, there is no rotation or linear movement and during measurement of the shape of the wafer 71, the wafer 71 and the multiple sensor devices are rotationally and linearly stationary. That is, the controller 602 is configured to determine the height of the wafer of the substrate above each of the multiple sensor devices while the substrate and the multiple sensor devices are rotationally and linearly stationary.

Measurement of the shape of the wafer may be achieved with no rotation of the multiple sensor devices relative to the wafer when three sensor devices are used because the edge height profile describes a double sine, of which the phase, amplitude and mean can be estimated from 3 statically sampled measurement points (relative to a flat wafer measurement at the same height), as long as the sensors are not placed in a redundant layout (e.g. opposite to each other). In particular, the parabolic description h=C1*x\hat{ }2+C2*y\hat{ }2 of a warped wafer means that the height at a fixed radius is described by a double cosine: h=A*cos(2*alpha+phi)+C over the angular position alpha. Amplitude A, phase offset phi and height offset C are the other mentioned parameters that together describe the warpage in two directions and angular orientation of the wafer. With three height measurement points (measured by three static sensor devices at non-redundant positions in the TSU 8 e.g. separated by an angular spacing of 120 degrees), the parameters A, C and phi can be estimated by a simple calculation. Then the warpage in two directions is: C+A (peaks) and C-A (valleys). The phase offset phi needs to be used in the pre-alignment later, then to backtrack and determine which warpage belongs to which exact axis (X or Y).

After pre-alignment, the Rz orientation and X/Y position of the wafer is known and therefore even two statically sampled sensor devices are sufficient to estimate the X/Y warpage. In particular, the angular orientation of the wafer needs to be very accurate on the wafer table WT because of alignment and exposure. Before transferring to the wafer table WT with a very repeatable and reproducible robot move, the angular orientation on the substrate support 704 is also very accurate. The wafer warpage follows the crystal lattice of the wafer, which means that with known wafer orientation after pre-alignment, the warpage in X- and Y-direction could be directly measured at two specific fixed sensor positions (e.g. 90 degrees apart) without rotating the wafer during the measurement.

Measurement of the shape of the wafer with no rotation of the multiple sensor devices relative to the wafer may be performed before or after the centering phase referred to above. Measurement of the shape of the wafer with no rotation of the multiple sensor devices relative to the wafer that is performed after the centering phase may achieve higher accuracy compared to being performed before the centering phase. This is because the XY offset of the wafer introduces a measurement disturbance, because a) the wafer deformation due to gravity is not as expected and b) the sensor devices will measure at another location on the wafer surface and c) the XY offset may cause an unpredictable substrate tilt.

In a further embodiment, the wafer may be flipped between measurements such that the opposite surface is measured by the one or more sensor devices according to the invention. Advantageously, gravity sag can be compensated by virtue of the linear association of measurements from each surface. This may be achieved, for example, via a simple addition or subtraction data operation.

Once the shape of the wafer is measured by the controller 602, information on the shape of the wafer can be used in many different ways (including exposure accuracy, wafer handling, and data gathering). The measure for the goodness-of-fit may also be used in the below examples.

In one example, exposure corrections may be made for accuracy in dependence on the shape of the wafer. In particular, the internal wafer stress and local deformation can be predicted and possibly corrected for in alignment, imaging or wafer positioning settings. Especially the wafer to wafer variation due to the warpage could be corrected for, instead of the larger lot-based correction loops that are implemented in known systems.

In another example, wafer clamping corrections may be made for accuracy in dependence on the shape of the wafer. The wafer clamping on the wafer table WT comprises pneumatics settings (like (i) flow rate of back fill gas that flows throughout the gap between wafer and wafer clamp to provide thermal conditioning of the wafer; and/or (ii) local momentary pressures between wafer and wafer clamp) and movements (of e-pins before/during takeover onto the wafer table WT) that determine the local stress and deformation in the wafer, and therefore the accuracy of the subsequent alignment and exposure. With a known warpage for instance an optimized flow rate (just high enough at the right moment to flatten and clamp, but not too high to induce only a minimum of stress) can be applied, improving overlay between lots, but particularly also wafer-to-wafer. This flow rate may not be constant over time for different wafers.

In another example, the shape of the wafer can be used to modify handling position/height parameters to enable successful takeovers between internal handling stations (e.g. grippers, p-chuck, other chucking positions) of the lithographic apparatus. In particular, warpage dependent heights can be used, so no vacuum errors occur when the wafer is locally at a slightly different position than expected for a flat wafer.

In another example, the shape of the wafer can be used to modify handling position/height/pneumatics parameters to prevent wafer and/or machine damage. For example, warpage-dependent handling heights may be applied to make wafers having specific warpages fit between two counterparts (bowl wafers protrude more upwards from typical handling positions, umbrellas more downwards). Also, on the TSU 8 itself for example, the amount of air pressure applied may be controlled in dependence on shape of the wafer (more air pressure at the edge is required for umbrella wafers to make sure it does not touch and scratch when the wafer is rotated).

The information on the shape of the wafer may be stored in memory in case the lithographic apparatus fails. The shape of the wafer can then be used during diagnostics of the machine failure.

The information on the shape of the wafer may also be used in for process control outside the lithographic apparatus. For example the shape of the wafer may be used by other measurement tools or wafer processing tools such as etching machines as part of a feedback/correction loop.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatuses. That is, embodiments of the present invention are not limited to measuring a shape of a wafer, and extend to measuring a shape of other substrates. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below. Other aspects of the invention are set-out as in the following numbered clauses:

1. A sensor system for measuring a shape of a substrate, comprising:
a substrate support to support a surface of the substrate,
at least one sensor device, each sensor device comprising an optical emitter to emit radiation beams onto the surface of the substrate, and an optical receiver to receive the radiation beams reflected from the surface; and
a controller configured to:
determine at least one measurement height of the surface of the substrate above each of the at least one sensor device, based on the received radiation beams;
compensate for gravitational sag of the substrate relative to a calibration height; and
determine the shape of the substrate based on a comparison of the calibration height and the at least one measurement height.
   2. The sensor system of clause 1, wherein the calibration height is predetermined and is obtained by retrieving the calibration height from a memory coupled to the controller.
   3. The sensor system of clause 1, wherein the controller is configured to obtain the calibration height based on received radiation beams reflected from a surface of a test substrate supported by the substrate support.
   4. The sensor system of any preceding clause, wherein the controller is configured to determine the at least one measurement height of the surface of the substrate above each of the at least one sensor device while the substrate and the at least one sensor device are rotated relative to each other.
   5. The sensor system of clause 4, wherein the substrate support is configured to rotate relative to the at least one sensor device.
   6. The sensor system of clause 4, wherein the at least one sensor device is configured to rotate relative to the substrate support.
   7. The sensor system of any preceding clause, wherein the controller is configured to determine the at least one measurement height of the surface of the substrate above each of the at least one sensor device while the substrate and the at least one sensor device are moved linearly relative to each other.
   8. The sensor system of clause 7, wherein the substrate support is configured to move linearly relative to the at least one sensor device.
   9. The sensor system of clause 7, wherein the at least one sensor device is configured to move linearly relative to the substrate support.
   10. The sensor system of any preceding clause, wherein the controller is configured to determine the at least one measurement height of the surface of the substrate above each of the at least one sensor device while the substrate and the at least one sensor device are rotated relative to each other by an angle of less than 270 degrees, preferably less than 225 degrees, and more preferably less than 180 degrees.
   11. The sensor system of any preceding clause, wherein the controller is configured to determine the at least one measurement height of the surface of the substrate above each of the at least one sensor device while the substrate and the at least one sensor device are rotated relative to each other by an angle of less than 135 degrees, preferably less than 90 degrees, and more preferably less than 45 degrees.
   12. The sensor system of any of clauses 1 to 3, wherein the controller is configured to determine the at least one measurement height of the surface of the substrate above each of the at least one sensor device while the substrate and the at least one sensor device are rotationally stationary.
   13. The sensor system of any preceding clause, wherein the substrate support is configured to vacuum clamp the substrate to the substrate support.
   14. The sensor system of any preceding clause, wherein the at least one sensor device comprises:
a first sensor device positioned along a first radius of the substrate; and
a second sensor device position along a second radius of the substrate, the first radius different to the second radius.
   15. The sensor system of clause 14, wherein the first sensor device is the only sensor device of the at least one sensor device that is positioned along the first radius.
   16. The sensor system of clause 14 or 15, wherein the second sensor device is the only sensor device of the at least one sensor device that is positioned along the second radius.
   17. The sensor system of any of clauses 14 to 16, wherein the first radius and the second radius are separated by an angle between 45 and 270 degrees, preferably between 90 and 225 degrees, more preferably between 135 and 180 degrees.
   18. The sensor system of any of clauses 14 to 17, wherein the at least one sensor device comprises:
a third sensor device positioned along a third radius of the substrate, the third radius different to the first radius and the second radius.
   19. The sensor system of clause 18, wherein the third sensor device is the only sensor device of the at least one sensor device that is positioned along the third radius.
   20. The sensor system of any of clauses 1 to 11, wherein the at least one sensor device comprises only a single sensor device.
   21. The sensor system of any preceding clause, wherein one or more of the at least one sensor device is a confocal chromatic sensor device.
   22. A lithographic apparatus comprising the sensor system of any preceding clause.

1. A sensor system for measuring a shape of a substrate, the sensor system comprising:
a substrate support to support a surface of the substrate;
at least one sensor device, each sensor device comprising an optical emitter to emit radiation onto the surface of the substrate, and an optical receiver to receive the radiation reflected from the surface; and
a controller configured to:
determine at least one measurement height of the surface of the substrate above each of the at least one sensor device, based on the received radiation;
compensate for gravitational sag of the substrate with respect to a calibration height; and
determine the shape of the substrate based on a comparison of the calibration height and the at least one measurement height.

2. The sensor system of claim 1, wherein the calibration height is predetermined and the controller is configured to obtain the calibration height from a memory coupled to the controller.

3. The sensor system of claim 1, wherein the controller is configured to obtain the calibration height based on received radiation reflected from a surface of a test substrate supported by the substrate support.

4. The sensor system of claim 1, wherein the controller is configured to determine the at least one measurement height of the surface of the substrate above each of the at least one sensor device while the substrate and the at least one sensor device are rotated relative to each other.

5.-6. (canceled)

7. The sensor system of claim 1, wherein the controller is configured to determine the at least one measurement height of the surface of the substrate above each of the at least one sensor device while the substrate and the at least one sensor device are moved linearly relative to each other.

8. The sensor system of claim 7, wherein the substrate support is configured to move linearly relative to the at least one sensor device.

9. The sensor system of claim 7, wherein the at least one sensor device is configured to move linearly relative to the substrate support.

10. The sensor system of claim 1, wherein the controller is configured to determine the at least one measurement height of the surface of the substrate above each of the at least one sensor device while the substrate and the at least one sensor device are rotated relative to each other by an angle of less than 270 degrees.

11. The sensor system of claim 1, wherein the controller is configured to determine the at least one measurement height of the surface of the substrate above each of the at least one sensor device while the substrate and the at least one sensor device are rotated relative to each other by an angle of less than 135 degrees.

12. The sensor system of claim 1, wherein the controller is configured to determine the at least one measurement height of the surface of the substrate above each of the at least one sensor device while the substrate and the at least one sensor device are rotationally stationary.

13. The sensor system of claim 1, wherein the substrate support is configured to vacuum clamp the substrate to the substrate support.

14. The sensor system of claim 1, wherein the at least one sensor device comprises:
a first sensor device positioned along a first radius of the substrate; and
a second sensor device positioned along a second radius of the substrate, the first radius different to the second radius.

15. The sensor system of claim 14, wherein the first sensor device is the only sensor device of the at least one sensor device that is positioned along the first radius.

16. The sensor system of claim 15, wherein the second sensor device is the only sensor device of the at least one sensor device that is positioned along the second radius.

17. The sensor system of claim 14, wherein the first radius and the second radius are separated by an angle between 45 and 270 degrees.

18. The sensor system of claim 14, wherein the at least one sensor device comprises a third sensor device positioned along a third radius of the substrate, the third radius different to the first radius and the second radius.

19. The sensor system of claim 18, wherein the third sensor device is the only sensor device of the at least one sensor device that is positioned along the third radius.

20. The sensor system of claim 1, wherein the at least one sensor device comprises only a single sensor device.

21. The sensor system of claim 1, wherein one or more sensor device of the at least one sensor device is a confocal chromatic sensor device.

22. A lithographic apparatus comprising the sensor system of claim 1.
